(19) United States
(12) Patent Application Publication
(10) Pub. No.: US 2026/0096476 A1
(43) Pub. Date: Apr. 2, 2026

(54) PLANAR TRANSFORMER WITH BRIDGE PASSIVE DEVICE

(71) Applicant: TEXAS INSTRUMENTS INCORPORATED, Dallas, TX (US)

(72) Inventors: Nicola Bertoni, Freising (DE); Giacomo Calabrese, Freising (DE)

(21) Appl. No.: 18/902,775

(22) Filed: Sep. 30, 2024

(51) Int. Cl. H01L 25/16; H01F 27/28; H01L 23/538

(52) U.S. Cl. CPC H10W 90/00; H01F 27/2804; H10D 1/20; H10W 70/611; H10W 70/685; H01F 2027/2809

(57) ABSTRACT

Described is an apparatus comprising a substrate, a first coil below a surface of the substrate, and a second coil below the surface of the substrate. The first coil has first and second ends. In at least one example, the second coil is laterally adjacent to the first coil, the second coil having third and fourth ends. The apparatus further comprises a semiconductor die on the surface of the substrate and coupled to the first and third ends via metal interconnects in the substrate. The apparatus comprises a passive component on the surface of the substrate and coupled between the second end and the fourth end, the passive component overlapping at least parts of the first and second coils.

### BACKGROUND

Isolation is often desirable for interconnecting electrical systems to exchange data or power between the systems. For example, two circuits may be powered by different supply sources that do not share a common ground connection. The two circuits may be electrically isolated to prevent current and voltages in one system from negatively impacting the other system, for instance by damaging or interfering with the operation of one or more components of the other system. One example circuitry to provide data and power isolation is a transformer including a primary side coil and a secondary side coil that are electrically isolated from each other, but the primary side coil can transmit power and data signal to the secondary side coil, and vice versa, via magnetic coupling between the coils. One example system including a transformer is an isolated DC-DC converter. Other examples of isolation circuitry include capacitors and piezoelectric devices.

### SUMMARY

Described here includes an apparatus comprising a substrate, a first coil below a surface of the substrate, and a second coil below the surface of the substrate. In at least one example, the first coil has first and second ends. In at least one example, the second coil is laterally adjacent to the first coil, the second coil having third and fourth ends. In at least one example, the apparatus further comprises a semiconductor die on the surface of the substrate and coupled to the first and third ends via metal interconnects in the substrate. In at least one example, the apparatus comprises a passive component on the surface of the substrate and coupled between the second end and the fourth end, the passive component overlapping at least parts of the first and second coils.

Described herein includes an apparatus, which comprises a substrate and a coil below a surface of the substrate, the coil having first and second ends, and a center tap between the first and second ends, the center tap being coupled to a ground/reference terminal. In at least one example, the apparatus comprises a semiconductor die on the surface of the substrate. In at least one example, the apparatus further comprises a first passive component on the surface of the substrate and coupled between the first end and the semiconductor die, the first passive component overlapping at least a part of the coil. In at least one example, the apparatus further comprises a second passive component on the surface of the substrate and coupled between the second end and the semiconductor die, the second passive component overlapping at least a part of the coil.

Described herein includes an apparatus which comprises a substrate and a coil below a surface of the substrate, the coil having first and second ends. The apparatus further comprises a semiconductor die on the surface of the substrate. The apparatus further comprises a capacitor on the surface of the substrate and coupled between the first end and the semiconductor die, the semiconductor die coupled to the second end via a metal interconnect in the substrate, the capacitor overlapping at least a part of the coil.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1A is a schematic depicting an example system having two semiconductor dies and an integrated isolation circuit comprising a transformer, in accordance with at least one example.

FIG. 1B is a schematic depicting an example system having two semiconductor dies and an integrated isolation circuit comprising a transformer, where each of the semiconductor die includes a receiver/transmitter, in accordance with at least one example.

FIGS. 2A, 2B, 2C, and 2D are schematics showing a power converter including a transformer, in accordance with various examples.

FIG. 3A is a schematic of a cross-section of a system with bridge passive devices and semiconductor dies on opposite surfaces of a substrate including a transformer, in accordance with at least one example.

FIGS. 3B, 3C, and 3D are schematics of isometric views of the system of FIG. 3A, in accordance with at least some examples.

FIG. 4 is a schematic of an isometric view of the system of FIG. 3A, in accordance with at least one example.

FIGS. 5A-C are schematics of an inductor with a bridge passive device, in accordance with various examples.

FIGS. 6A-C are schematics of an inductor with multiple bridge passive devices, in accordance with at least some examples.

FIGS. 7A-C are schematics of cross sections of a substrate including a transformer, in accordance with various examples.

### DETAILED DESCRIPTION OF EXAMPLE EMBODIMENTS

Described here is a system including a planar transformer in a substrate. The planar transformer includes a first coil below a first surface of the substrate, the first coil having first and second ends, in which the second end is laterally separated from the first end by at least part of the first coil. The first coil is the primary winding of the transformer. The substrate includes a first metal layer and a second metal layer, wherein the primary winding is in the first metal layer and the second metal layer is configured as a ground shield. The first metal layer can be vertically between the first surface and the second metal layer. The substrate has a second surface opposite the first surface. In at least one example, the planar transformer comprises a second coil below the second surface of the substrate, the second coil having third and fourth ends, in which the fourth end is laterally separated from the third end by at least part of the second coil. The second coil is the secondary winding of the transformer. In at least one example, the substrate further includes a third metal layer and a fourth metal layer, wherein the third metal layer is configured as a ground shield while the secondary winding is in the fourth metal layer. The fourth metal layer is vertically between the third metal layer and the second surface. In at least one example, the substrate includes an isolation barrier material (e.g., dielectric material) between the second metal layer and the third metal layer. The isolation barrier material provides galvanic isolation between the primary and secondary windings of the planar transformer.

In at least one example, the system includes a first semiconductor die on the first surface of the substrate. The first semiconductor die may comprise a full bridge inverter. The first end of the first coil can be proximate the first semiconductor die, and the second end of the first coil can be laterally separated from the first semiconductor die by at least part of the first coil. The system also includes a first passive component (e.g., capacitor, resistor, or bond wire) where the first semiconductor die may be coupled to the second end of the first coil via the first passive component. In at least one example, the first passive component is on the first surface of the substrate and coupled between the second end of the first coil and the first semiconductor die, where the first passive component overlaps and bridges across at least a part of the first coil to provide an electrical connection between the first semiconductor die and the second end of the first coil. The first semiconductor die is coupled to the first end of the first coil via a first metal interconnect, which can be part of the first metal layer of the substrate. In some examples, the primary winding includes an additional coil to provide a symmetric winding, and the first semiconductor die can be coupled to the the primary winding via multiple passive components.

In at least one example, the system includes a second semiconductor die on the second surface of the substrate. The second semiconductor die may include a rectifier. The third end of the second coil can be proximate the second semiconductor die, and the fourth end of the second coil can be laterally separated from the second semiconductor die by at least part of the second coil. The system may include a second passive component (e.g., capacitor, resistor, or bond wire), where the second semiconductor die may be coupled to the fourth end of the second coil via the second passive component. In at least one example, the second passive component is on the second surface of the substrate and coupled between the fourth end and the second semiconductor die, where the second passive component overlaps and bridges across at least a part of the second coil to provide an electrical connection between the second semiconductor die and the fourth end of the second coil. The second semiconductor die is coupled to the third end of the second coil via a second metal interconnect, which can be part of the fourth metal layer of the substrate. In some examples, the secondary winding includes an additional coil to provide a symmetric winding, and the first semiconductor die can be coupled to the secondary winding via multiple passive components.

In at least one example, the first and second coils are spiral coils. In at least one example, the first and second coils are figure-of-8 coils. In at least one example, the first and second coils are figure-of-B coils. The figure-of-8 and figure-of-B coils are symmetric coils. In at least one example, the first and second coils have air cores. In at least one example, the first and second coils have cores filled with the dielectric material of the substrate. In at least one example, the first and second coils have ferrite cores, or cores made of other materials different from the substrate.

The transformer of various examples can provide lower cost and reduced form factors. Specifically, in examples where the first and second coils have air/dielectric cores, such examples can be fabricated at a lower cost. Such examples can also have smaller form factors and provide less electromagnetic emission than transformers with ferrite cores. Further, using passive components as bridge can reduce the need for blind/buried vias, which can reduce cost. Form factor can also be reduced due to the clearance requirement of the blind/buried vias being relaxed/removed.

Also, symmetric coils described herein for primary and secondary windings improve electromagnetic interference (EMI) performance over a wide frequency band as emissions from one coil are cancelled by emissions from the other coil. Further, the symmetric coils allow the transformer to reliably send data streams across the isolation barrier. A non-symmetric coil may radiate magnetic energy, and the radiation power increases with the size of the coil. In contrast, magnetic field cancellation may occur in the figure-of-8 coil due to its symmetry and because the half of the coil is clockwise and another half of the coil is counterclockwise, so that magnetic fields in the two halves of the coils can cancel. In a case where the transformer is small (e.g. integrated in the package), the transformer may also generate electromagnetic radiation due to printed circuit board (PCB) ground bounce caused by common mode current. This effect is also cancelled by the symmetric coils such as figure-of-B and figure-of-8 coils.

In addition, the ground shields are coupled to ground planes adjacent to the coils. The ground shields can not only shield the coils from noise but also conduct heat away from the coils to the ground planes, which can function as heat sinks. Such arrangements can provide thermal management, which improve the maximum power transfer capabilities of the transformer. Further, the ground planes can also be part of Faraday shields, which can also be used as heat sinks and to improve EMI and lower emissions.

The substrate of various examples can be a package substrate of a packaged IC, or a PCB of a system. The shape of the primary and secondary windings, the use of substrate or PCB layers as heat sinks, and surface mount passive devices (e.g., resistors, capacitors, or bond wires) reduce the layer count and/or avoid blind/buried vias, which in turn reduces cost. The capacitors and the transformers can also be part of a resonant power converter. The transformer configuration of various examples can be implemented as parallel-resonant and series-resonant topologies.

In the drawings, like reference numerals refer to like elements throughout, and the various features are not necessarily drawn to scale. Here, the same reference numbers or other reference designators are used in the drawings to designate the same or similar (either by function and/or structure) features.

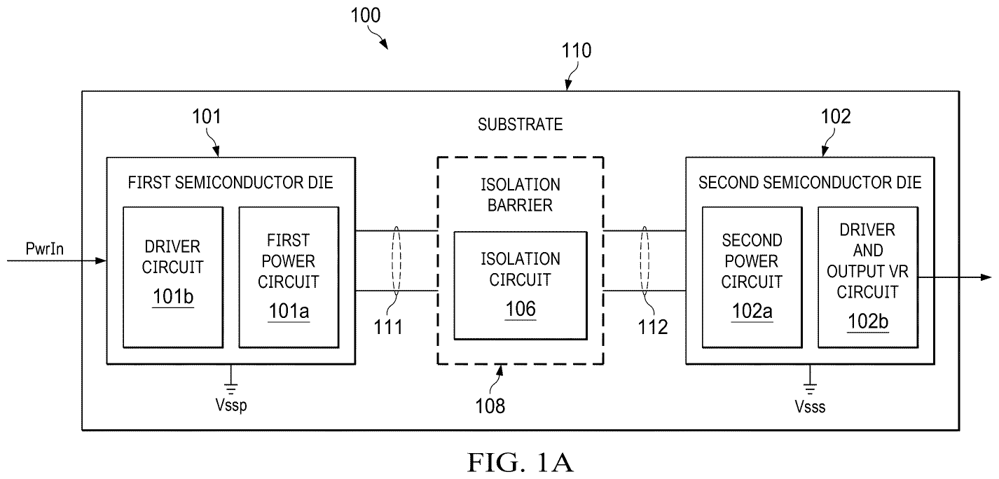

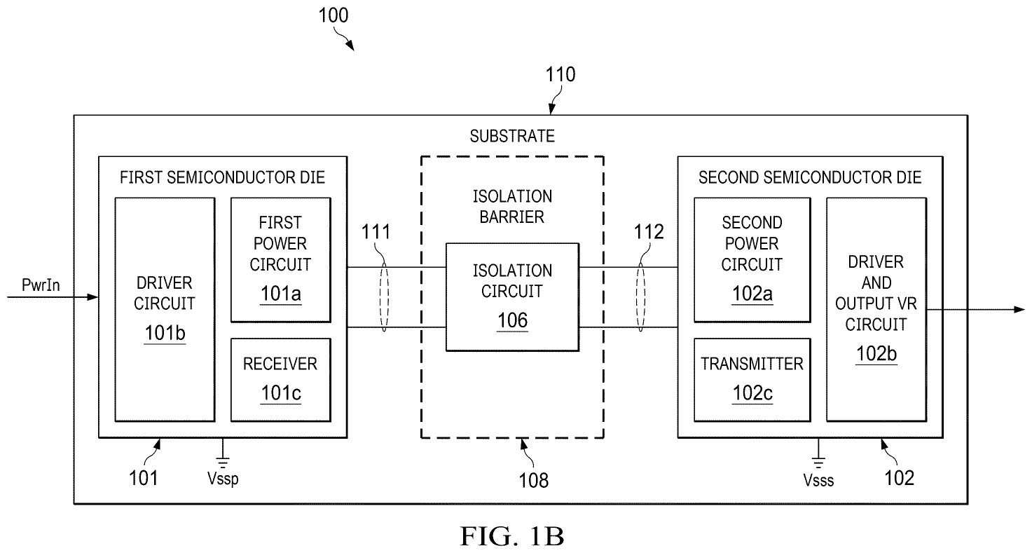

FIG. 1A is a schematic depicting an example system 100 having two semiconductor dies and an integrated isolation circuit comprising a transformer, in accordance with at least one example. In some example, system 100 is a packaged IC. In some examples, system 100 can include multiple packaged ICs. System 100 includes a first semiconductor die 101, and a second semiconductor die 102, an integrated isolation circuit 106, an isolation barrier 108, and a substrate 110. First and second semiconductor dies 101 and 102 are mounted to substrate 110, which can support first and second semiconductor dies 101 and 102 as a circuit support structure. In examples where system 100 is a packaged IC, substrate 110 can be part of a package substrate, which can include a lead frame, and first and second semiconductor dies 101 and 102 can be covered by a mold compound (not shown in the figures). In examples where system 100 includes multiple packaged ICs, each of semiconductor dies 101 and 102 can be a packaged IC (or a chip), and substrate 110 can be a circuit board, such as a printed circuit board (PCB)).

In at least one example, integrated isolation circuit 106 is integrated, formed, or embedded into layers (not shown) of substrate 110. In at least one example, substrate 110 includes contact pads (not shown) and may include metallic interconnects 111 and 112 (four shown) to allow interconnectivity between first and second semiconductor dies 101 and 102, and integrated isolation circuit 106. Each interconnect 111 and 112 may represent power and/or data channels with one or more electrical traces and/or vias.

In at least one example, integrated isolation circuit 106 (and other isolation circuit examples in accordance with this description) may provide a galvanic isolation barrier between two different power domains. In at least one example, integrated isolation circuit 106 is a planar transformer. In at least one example, the transformer is spiral shaped and includes two coils separated by isolation barrier 108, which can be provided by the dielectric material of substrate 110. In at least one example, the transformer is a figure-of-8 or figure-of-B shaped transformer comprising a primary winding and a secondary winding that are separated by isolation barrier 108 between them. The transformer can have an air core, a core made of the dielectric material of substrate 110, or a core made of a different material from the dielectric material of substrate 110 (e.g., a ferrite core). In at least one example, the primary winding is in a top metal layer of substrate 110, while the secondary winding is in the bottom metal layer of substrate 110. The isolation barrier is between the top metal layer and the bottom metal layer. In at least one example, there is an additional isolation barrier between the primary winding and surfaces of first and second semiconductor dies 101 and 102, respectively.

In at least one example, the additional isolation barrier is a first isolation barrier and includes part of substrate 110 and part of a mold compound surrounding first and second semiconductor dies 101 and 102, respectively. The first isolation barrier provides isolation between first and second semiconductor dies 101 and 102 and integrated isolation circuit 106 (e.g., an inductive isolation circuit such as a transformer) that different power supply domains can be used for first and second semiconductor dies 101 and 102, while allowing first and second semiconductor dies 101 and 102 to overlap integrated isolation circuit 106. In at least one example, a second isolation barrier is formed between the primary winding and the secondary winding of the transformer and is part of substrate 110, to provide galvanic isolation between the primary and secondary windings. The second isolation barrier allows the metal layers for the primary winding and secondary winding to now have smaller gaps (e.g., reduced clearance specification).

In at least one example, first semiconductor die 101 is on a top surface of substrate 110, while second semiconductor die 102 is on a bottom surface of substrate 110. In at least one example, first semiconductor die 101 may be coupled to the primary winding via one or more first passive components (e.g., capacitor, resistor, or bond wire) which are not shown in FIG. 1A. The one or more first passive components can bridge over and overlap at least part of the primary winding. In at least one example, the first one or more passive components are on the top surface of substrate 110 and coupled between an end of the primary winding and first semiconductor die 101. In at least one example, second semiconductor die 102 may be coupled to the secondary winding via one or more second passive components (e.g., capacitor, resistor, or bond wire) which are not shown in FIG. 1A. The one or more second passive components can bridge over and overlap at least part of the secondary winding. In at least one example, the second one or more passive components are on the bottom surface of substrate 110 and coupled between an end of the secondary winding and second semiconductor die 102.

In at least one example, substrate 110 includes ground planes adjacent to the primary winding and the secondary winding and separated by a dielectric material. The ground planes are configured as heat sinks to conduct heat away from the isolation circuit 106.

In at least one example, system 100 can include a direct current (DC)-to-DC converter having the transformer as integrated isolation circuit 106. In at least one example, the DC-to-DC converter comprises circuits in first semiconductor die 101 and second semiconductor die 102 coupled via the transformer. Accordingly, first semiconductor die 101 may include circuits, such as a first power circuit 101a (e.g., half-bridge circuit, a full-bridge circuit, or an inverter) and a driver circuit 101b, for providing a voltage and a current from other circuit to a primary winding of the transformer. In at least one example, the voltage and the current are provided from a power supply external to system 100.

In at least one example, second semiconductor die 102 may include circuits, such as a second power circuit 102a (e.g., half-bridge or a full-bridge rectifier) and a driver and voltage regulation (VR) circuit 102b for receiving a voltage and a current from the secondary winding of the transformer and providing one or more regulated output voltages and/or currents for use by a load. The load may be an application-specific integrated circuit (ASIC), a field-programmable gate array (FPGA), a microcontroller, a processor, etc. In at least one example, first and second semiconductor dies 101 and/or 102 may represent controller circuit, current and voltage sensors, gate drivers for insulated-gate bipolar transistors, gate drivers for field effect transistors (FETs), etc.

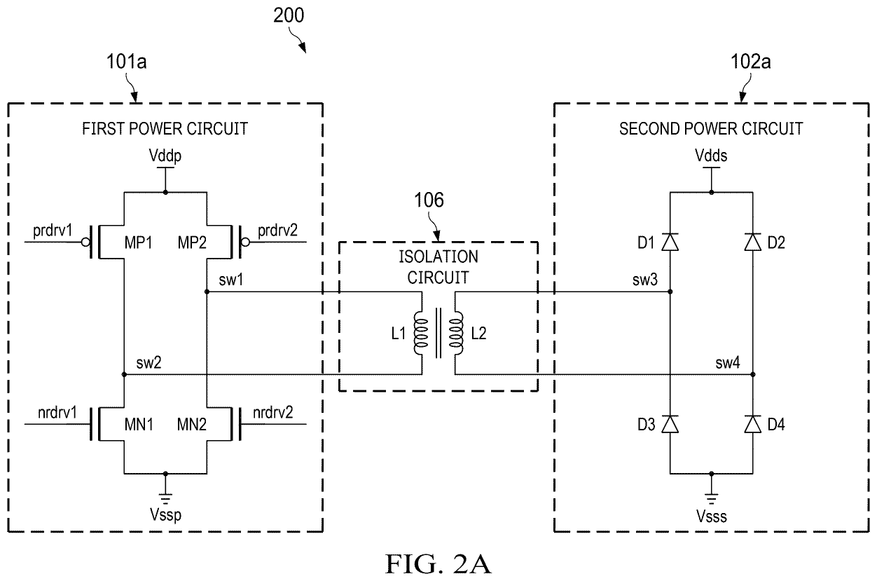

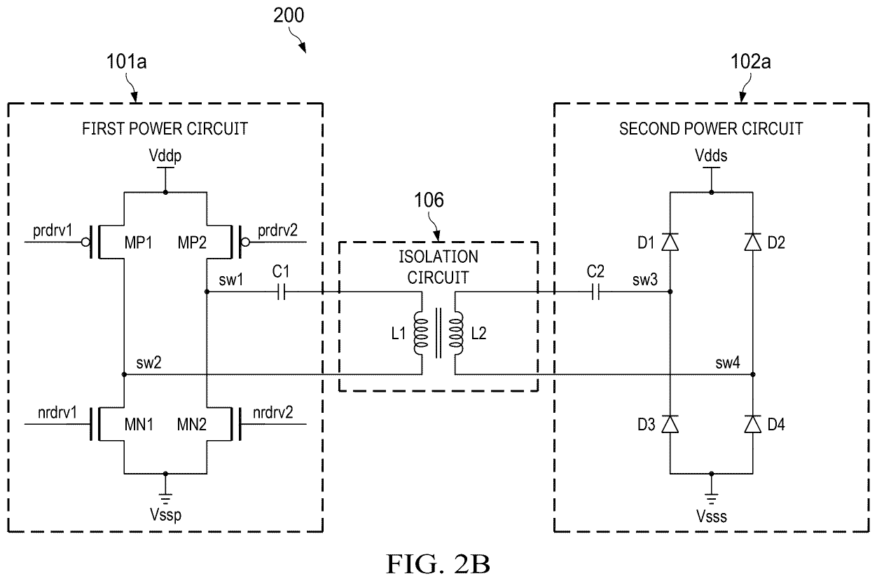

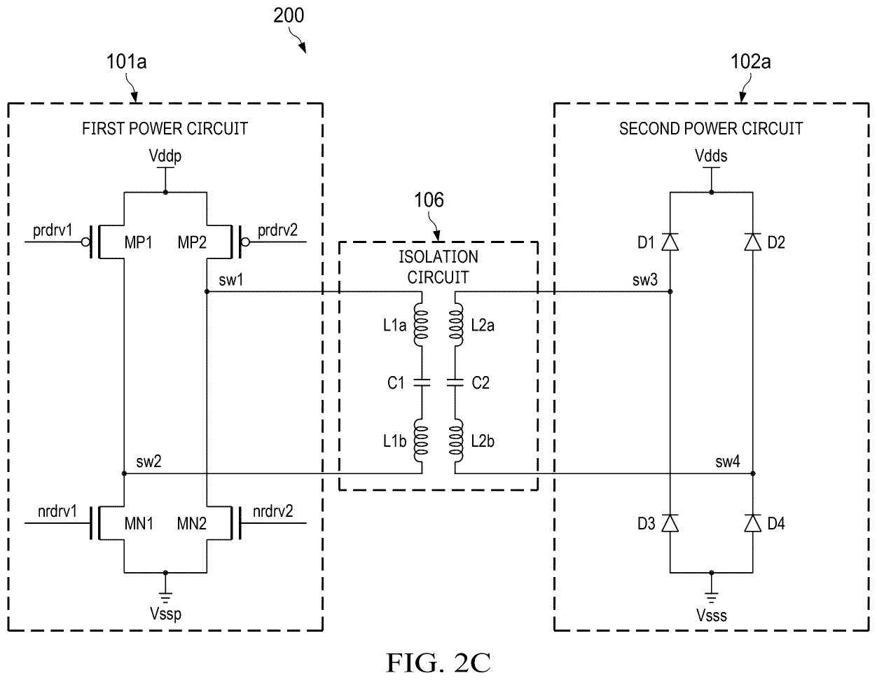

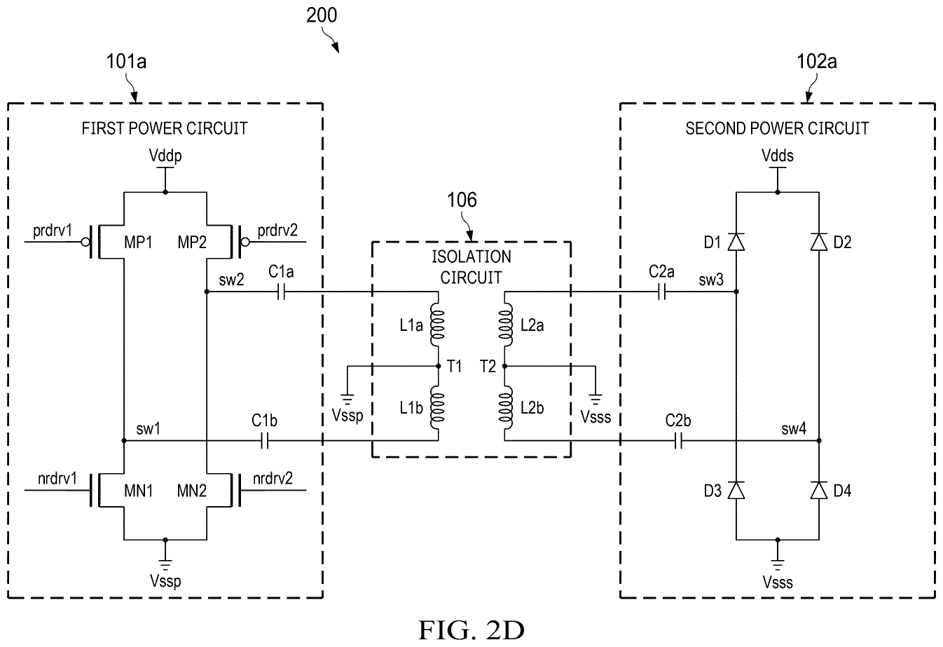

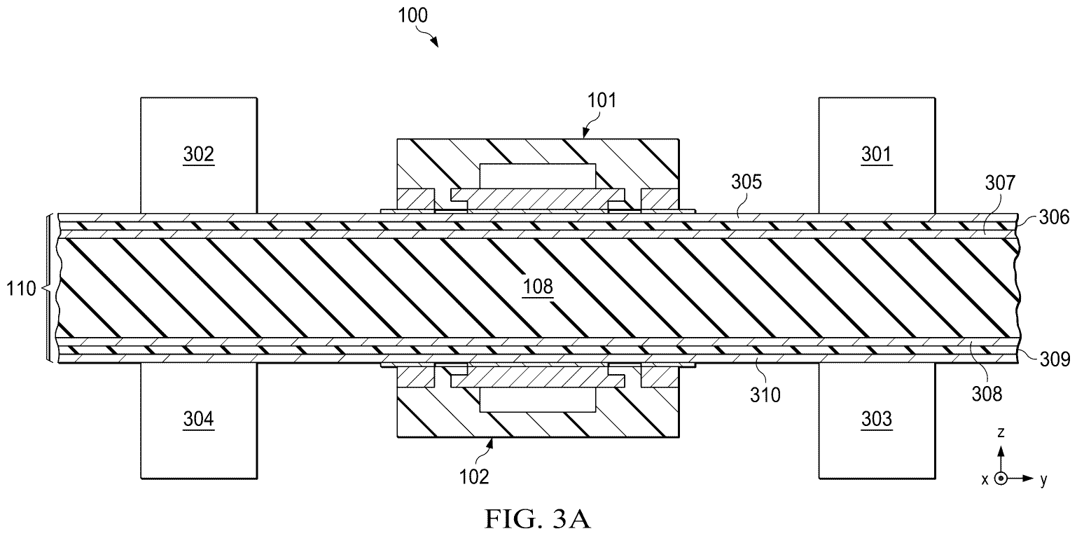

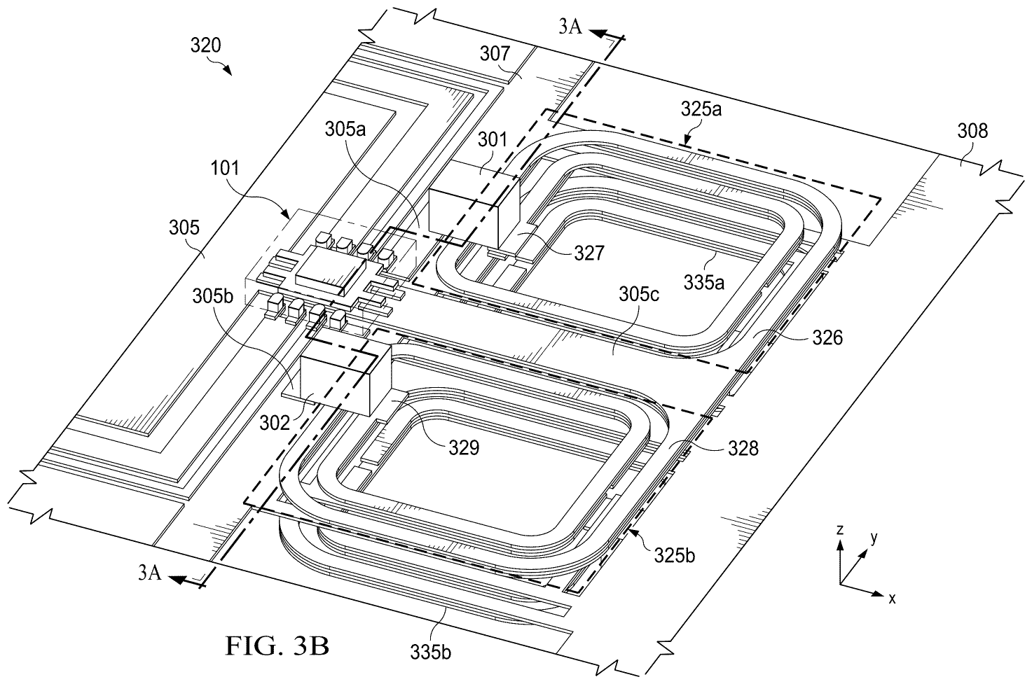

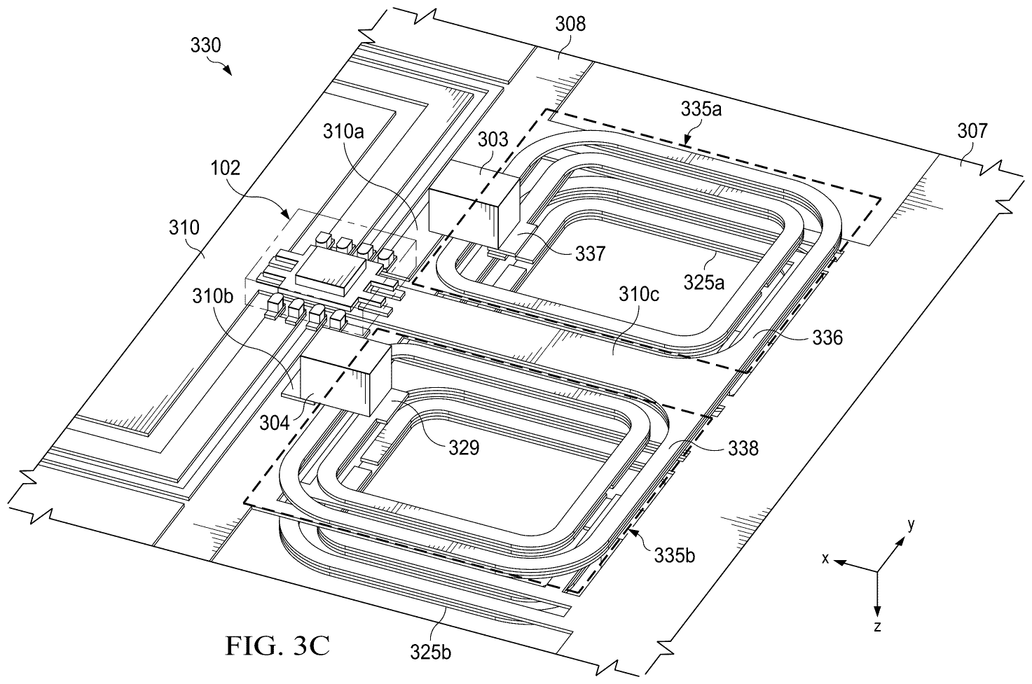

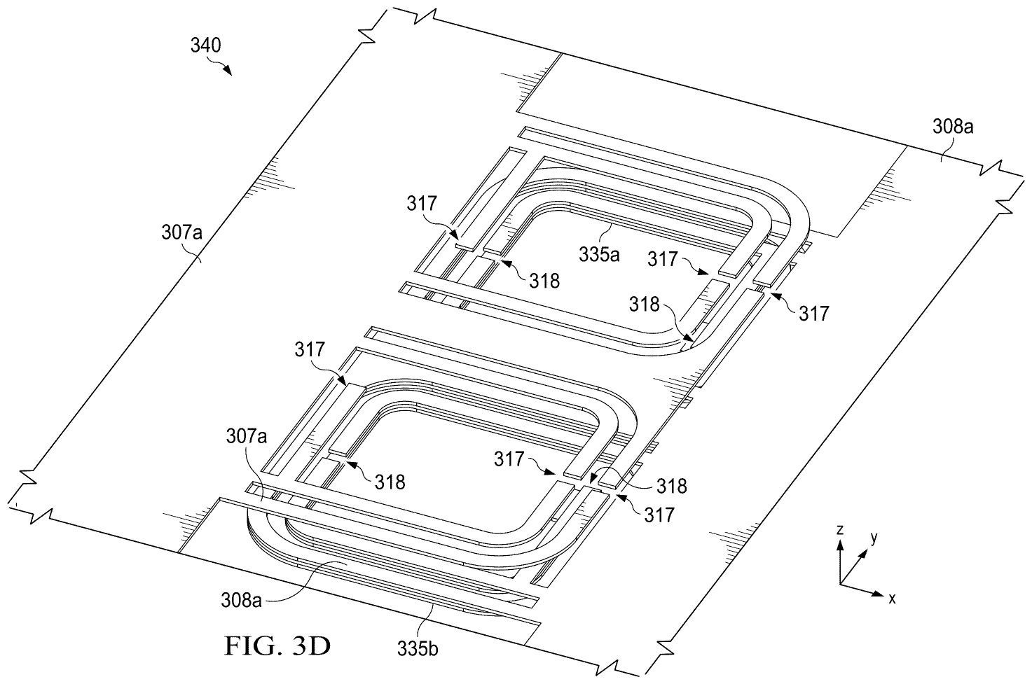

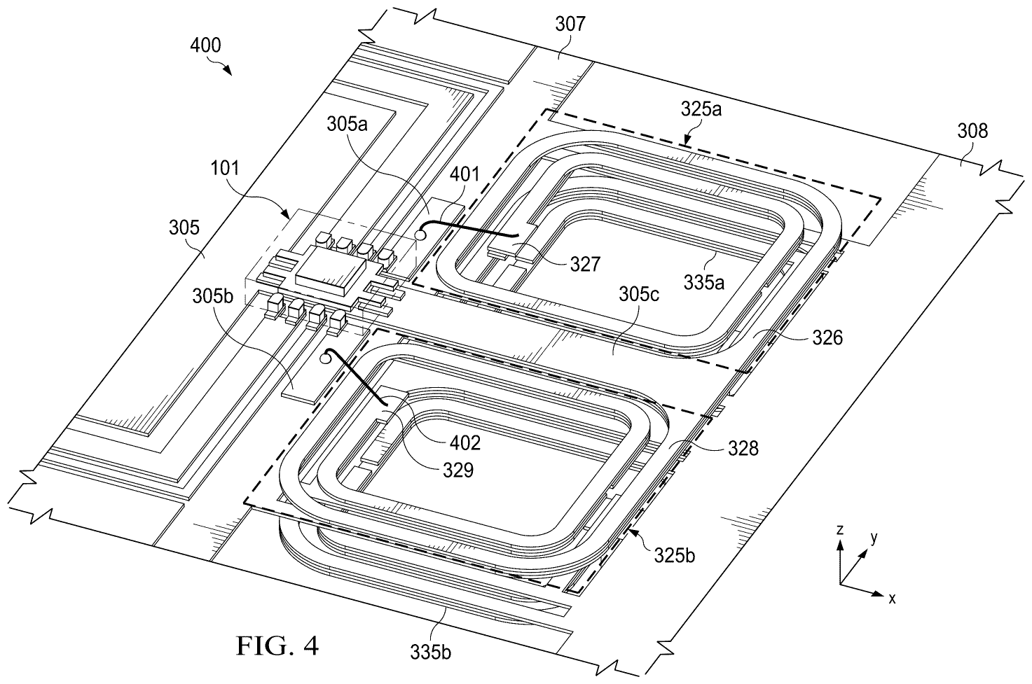

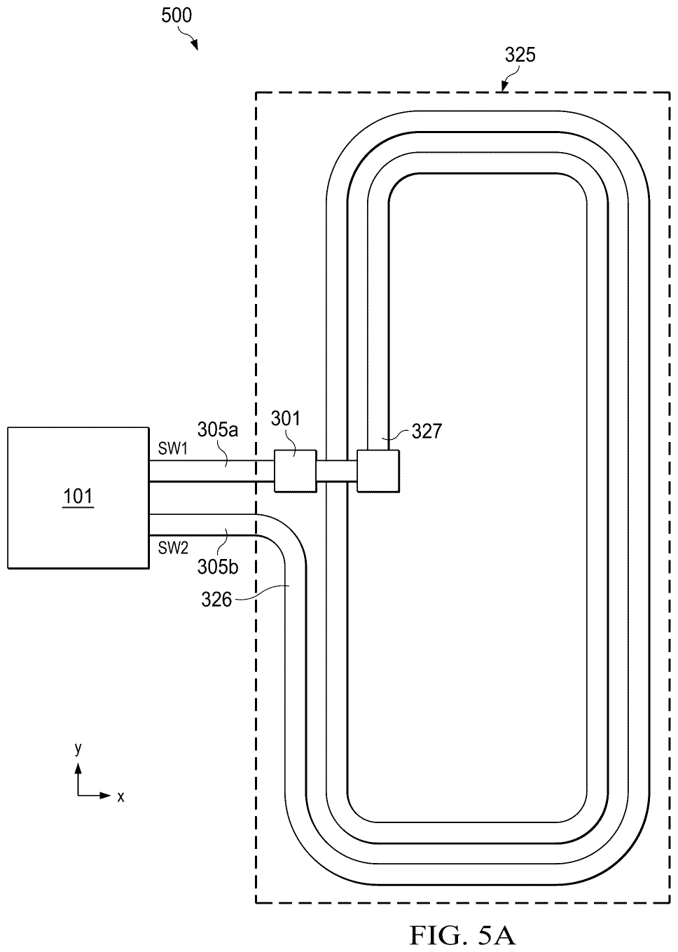

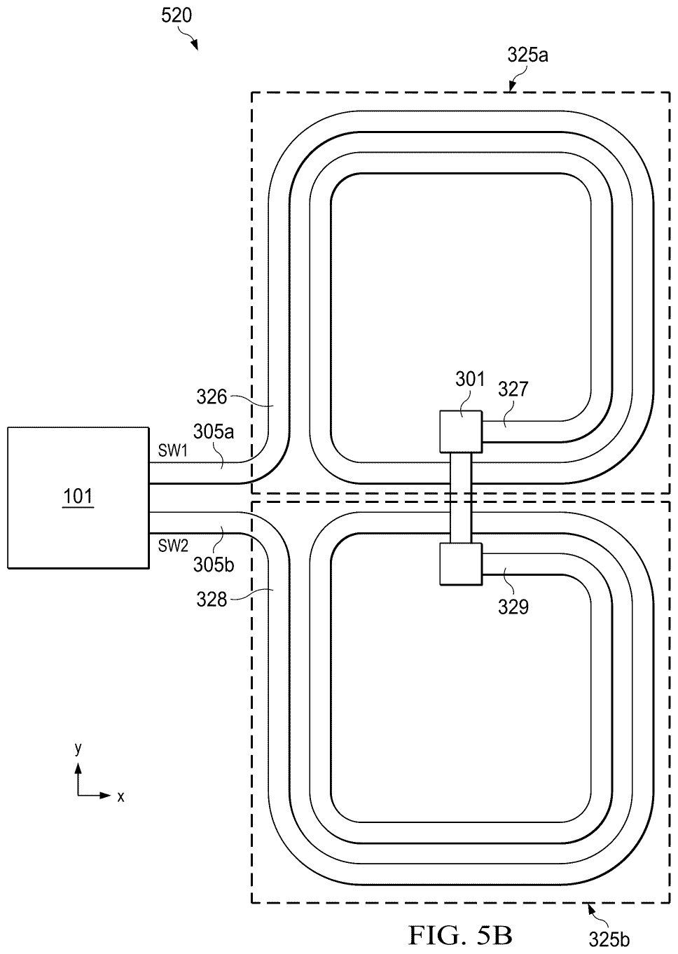

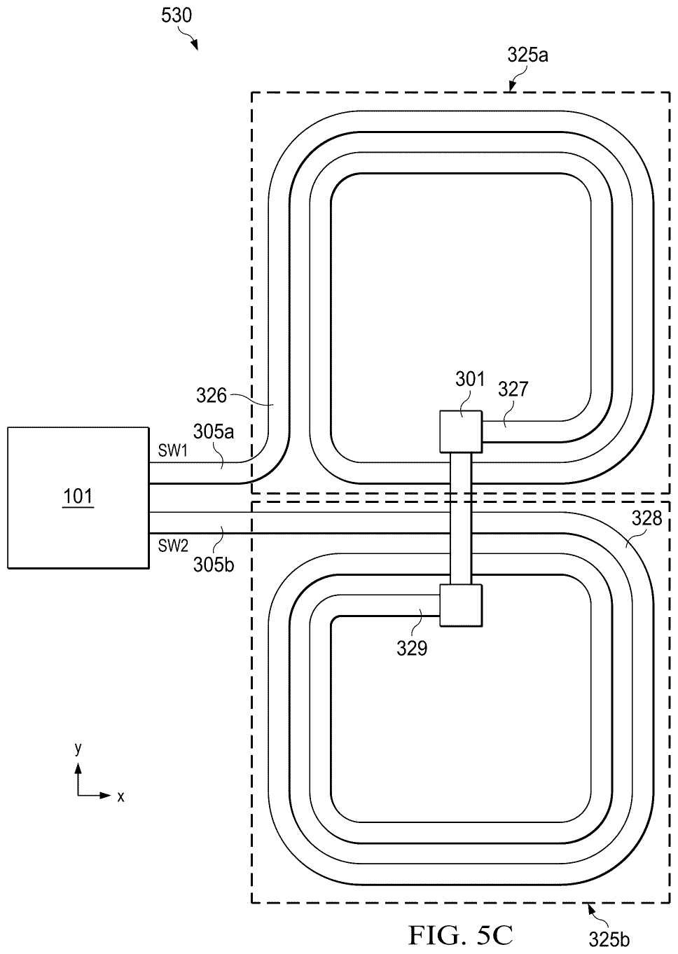

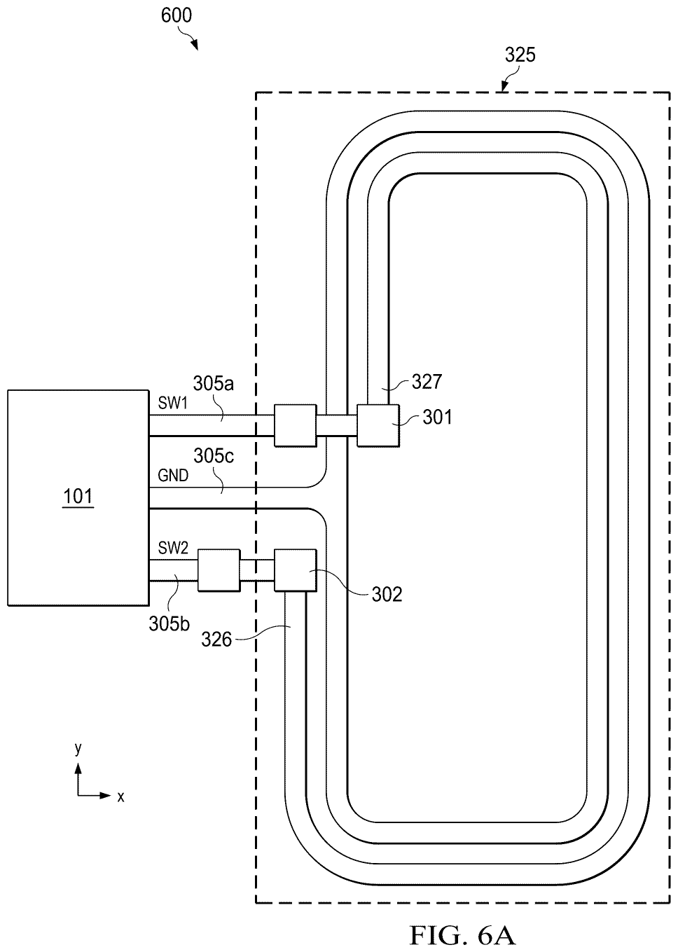

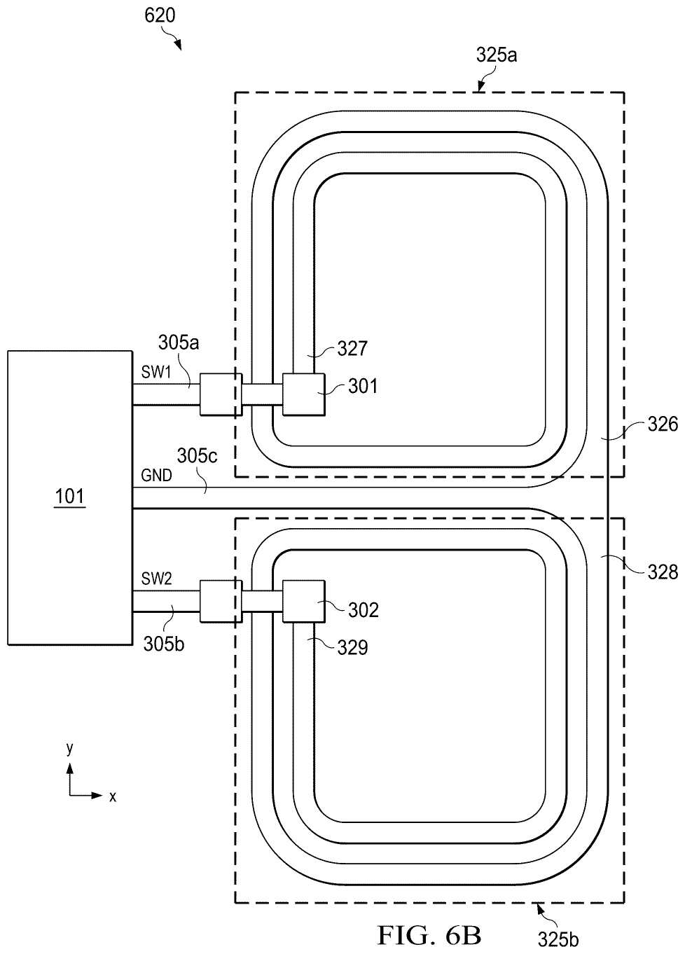

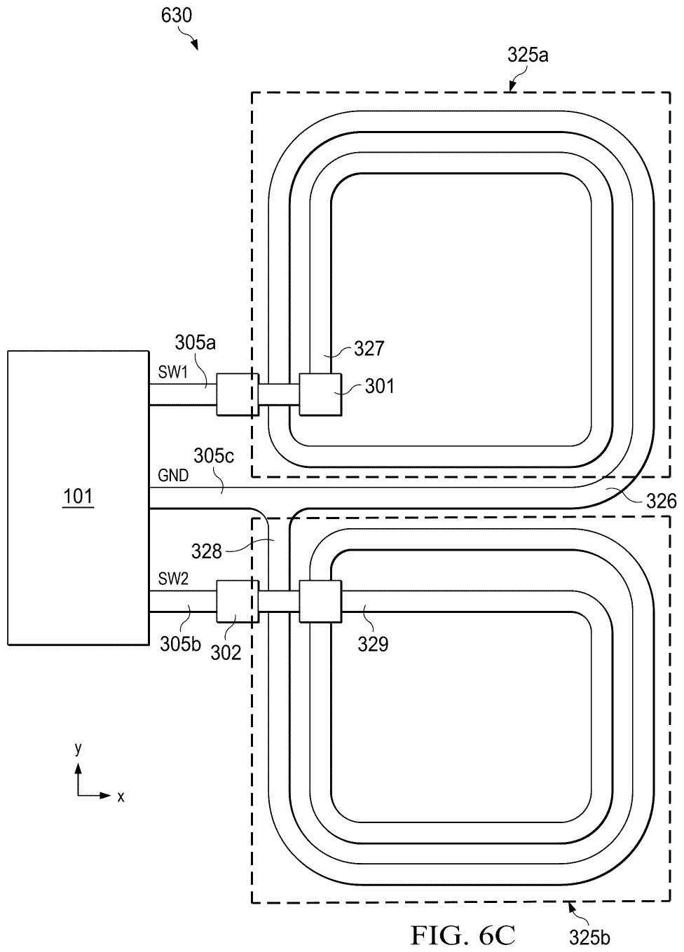

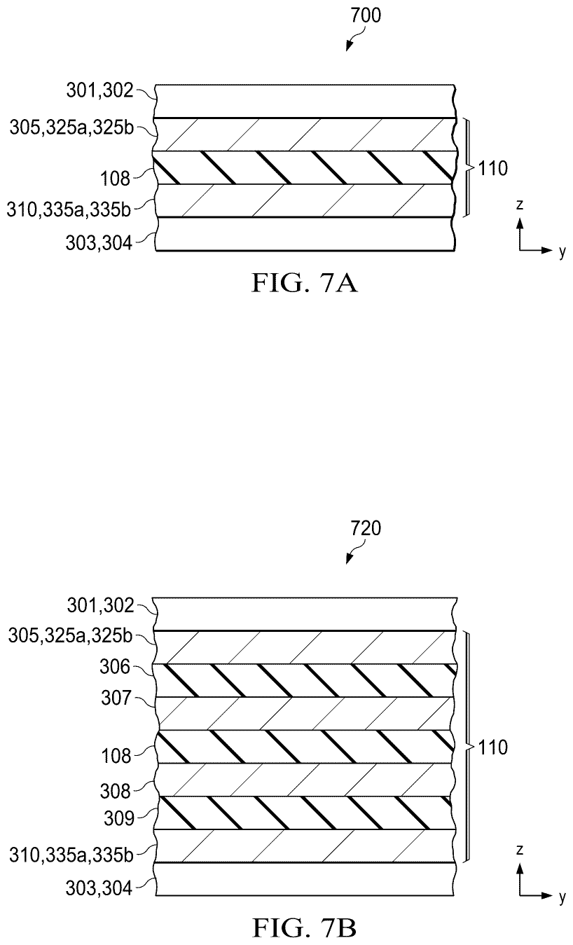

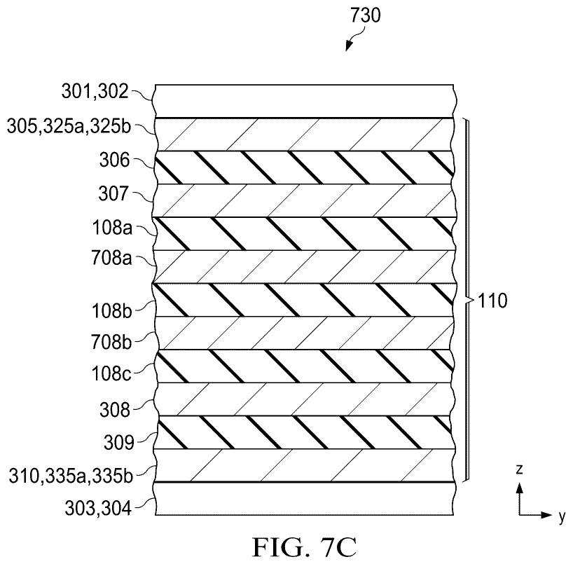

In at least one example, integrated isolation circuit 106 may be one or more transformers, for instance as shown in FIGS. 2A-2D, FIGS. 3B-D, FIG. 4, FIGS. 5A-C, and FIGS. 6A-C. Further various configurations of stack of layers of substrate 110 are illustrated in FIGS. 7A-C.

FIG. 1B is a schematic depicting an example packaged IC having two semiconductor dies, and an integrated isolation circuit comprising an inductive isolation circuit such as a transformer, where each of the semiconductor dies includes a receiver/transmitter, in accordance with at least one example. In at least one example, first semiconductor die 101 includes receiver 101c, and second semiconductor die includes transmitter 102c. Output from transmitter 102c is coupled to the transformer in substrate 110 to receiver 101c. As such, both data signals and power can be transmitted over the transformer. Examples of arrangements of using a transformer to transmit both data signals and power are described in related U.S. application Ser. No. 17/363,470, filed on Jun. 30, 2021, titled “Data transfer through an isolated power converter,” which is hereby incorporated by reference by its entirety. The data signals may be used to control or regulate operation of the DC-DC converter. For instance, feedback from the inverter of second power circuit 102a is transmitted over the transformer to receiver 101c to control switching speed, threshold level, and/or supply level of first power circuit 101a. The data signals can be used for other functions such as telemetry, data signaling, buffering of analog input signals for an analog-to-digital converter, buffering of digital input signals for a digital-to-analog converter, etc. In at least one example, the transformer can be multiplexed between sending internal data (e.g., feedback data from a secondary side back to a primary side within system 100), external data (e.g., external to system 100), and power.

FIG. 2A, FIG. 2B, FIG. 2C, and FIG. 2D are schematics showing examples of a DC-DC converter 200 that can be part of system 100 of FIGS. 1A and 1B. In at least one example, DC-DC converter 200 comprises first power circuit 101a, second power circuit 102a, and an inductive isolation circuit 106, such as a transformer including a primary winding L1 and a secondary winding L2. Both primary winding L1 and secondary winding L2 are planar inductors and can include spiral coils, with air cores, dielectric cores, or ferrite cores. The spiral inductors can provide higher coupling coefficient k and quality factor Q for the same area than other inductor topologies. Also, inductors with air cores and dielectric cores can be fabricated with reduced cost and can also provide less electromagnetic emission than inductors with ferrite cores. In at least one example, first power circuit 101a comprises p-type transistors (e.g., field effect transistors (FETs)) MP1 and MP2 coupled to primary side power supply terminal Vddp, and n-type transistors MN1 and MN2 coupled to primary side ground terminal Vssp.

Transistor MP1 is controllable by a control signal pdrv1, transistor MP2 is controllable by a control signal pdrv2, transistor MN1 is controllable by a control signal ndrv1, and transistor MN2 is controllable by a control signal ndrv2. Transistors MP1 and MP2 are high-side switches, while transistors MN1 and MN2 are low-side switches. High-side switches are turned on and off by pdrv1 and pdrv2. In at least one example, data circuits 101b and/or 102b generate pdrv1 and pdrv2 signals based on a desired regulated output voltage and a reference voltage. Low-side switches are turned on and off by ndrv1 and ndrv2. In at least one example, data circuit 101b and/or 102b generate ndrv1 and ndrv2 signals based on the desired regulated output voltage and the reference voltage. High-side switches are coupled in series with low-side switches at switching terminals sw1 and sw2. The primary winding L1 of inductive isolation circuit/transformer 106 is coupled between switching terminals sw1 and sw2.

In at least one example, second semiconductor die 102 includes two sets of diodes that are coupled in parallel. These diodes include diodes D1 and D2 coupled to secondary side power supply terminal Vdds, and diodes D3 and D4 coupled to secondary side ground terminal Vsss and to diodes D1 and D2. Diodes D1 and D3 are coupled at a third switching terminal sw3, and diodes D2 and D4 are coupled at a fourth switching terminal sw4. The secondary winding L2 of transformer 106 are coupled between the third and fourth switching terminals.

Power can be transmitted from the primary side power supply Vddp via the switching of first power circuit 101a and the transformer to second power circuit 102a and provided via the second side power supply terminal Vdds. Diodes D1, D2, D3, and D4 can provide rectification. While DC-DC converter 200 is illustrated as one example, other examples of DC-DC converters can be employed that use the transformer as integrated isolation circuit 106.

FIG. 2A, FIG. 2B, FIG. 2C, and FIG. 2D also show different power converter topologies. In FIG. 2A, the primary winding L1 is DC-coupled (e.g., via a zero-ohm resistor, a bond wire, etc.) to switching terminals sw1 and sw2, and the secondary winding L2 is DC-coupled (via a zero-ohm resistor, a bond wire, etc.) to switching terminals sw3 and sw4. In examples shown in FIG. 2B, FIG. 2C, and FIG. 2D, the power converter can be a resonant power converter, in which the primary winding L1 is coupled to switching terminals sw1 and sw2 via one or more capacitors, and the secondary winding L2 is coupled to switching terminals sw3 and sw4 via one or more capacitors, or each winding includes coils that are coupled via a capacitor. The resonant frequency of the resonant transformer can be configured based on, for example, the capacitance of the capacitors.

Specifically, in FIG. 2B, an end of primary winding L1 is coupled to switching terminal sw2 via a capacitor C1, and an end of secondary winding L2 is coupled to switching terminal sw3 via a capacitor C2. Also, in FIG. 2C, primary winding L1 includes coils L1a and L1b, and a capacitor C1 is coupled between L1a and L1b. Each of coils L1a and L1b are DC-coupled to, respectively, switching terminals sw2 and sw1. Also, secondary winding L2 includes coils L2a and L2b, and a capacitor C2 is coupled between L2a and L2b. Each of coils L2a and L2b are DC-coupled to, respectively, switching terminals sw3 and sw4. Also, in FIG. 2D, primary winding L1 includes coils L1a and L1b, and secondary winding includes coils L2a and L2b. One end of L1a is coupled to switching terminal sw2 via a capacitor C1a, and another end of L1a is coupled to a center tap T1, which is coupled to primary side ground terminal Vssp. Also, one end of L1b is coupled to switching terminal sw1 via capacitor C1b, and another end of L1b is coupled to center tap T1. Further, one end of L2a is coupled to switching terminal sw3 via a capacitor C2a, and another end of L2a is coupled to a center tap T2, which is coupled to secondary side ground terminal Vsss. Also, one end of L2b is coupled to switching terminal sw4 via capacitor C2b, and another end of L2b is coupled to center tap T2.

Different examples of primary and secondary windings and connection topologies in FIG. 2B, FIG. 2C, and FIG. 2D can also be combined. In some examples, a power converter can include primary winding L1 and capacitor C1 of FIG. 2B, and secondary windings L2a and L2b and capacitor C2 of FIG. 2C or the secondary windings L2a and L2b, capacitors C2a and C2b, and center tap T2 of FIG. 2D.

As to be discussed below, in all these examples, one or more of the capacitors (e.g., C1, C2, C1a, C2a, etc.) can be positioned on the substrate to bridge over part of the primary or secondary winding and provide an alternating current (AC) electrical connection between, for example, a winding and a semiconductor die, or between coils of a winding. Such arrangements can reduce the need for blind via/buried via, which can reduce cost. Form factor of the transformer can also be reduced due to removal/relaxation of clearance requirements imposed by the blind via/buried via. In some examples, these capacitors can be discrete components external to the semiconductor dies. In some examples, these capacitors can be integrated with the semiconductor dies (e.g., metal caps in the metallization structure).

The various primary/secondary windings and capacitor connections in FIG. 2B, FIG. 2C, and FIG. 2D can provide various additional advantages. For example, in the example of FIG. 2B, by using one capacitor per inductor, capacitor mismatch issues are mitigated. Also, in the example of FIG. 2C, inductor coils L1a and L1b can be symmetrical, and L2a and L2b can also be symmetrical, which can cancel or reduce electromagnetic emissions. Symmetric coils L1a and L1b, and L2a and L2b, in a figure-of-B configuration provide better far field EMI, while symmetric coils L1a and L1b, and L2a and L2b, in a figure-of-8 configuration provide lower radiated near field (e.g., reduced emissions). Symmetric coils also allow for reliable communication over the transformer.

Further, in the example of FIG. 2D, the capacitors C1a and C1b can represent capacitor C1 of FIG. 2C, and the capacitors C2a and C2b can represent capacitor C2 of FIG. 2C. Coils L1a and L1b can be symmetrical, and can be in a figure-of-8 or a figure-of-B configuration. Coils L2a and L2b can also be symmetrical, and can also be in a figure-of-8 or a figure-of-B configuration. The symmetrical inductor coils L1a and L1b, and L2a and L2b can cancel or reduce electromagnetic emissions. Also, center tap ground terminals allow to better shunt the common mode transient (CMT) current to ground without flowing through the IC thus providing increased immunity of the IC to ground transients/noise.

FIG. 3A is a schematic of a cross-section of system 100 with passive devices on top and bottom surfaces of substrate 110, where the inductive isolation circuit/transformer 106 is embedded in substrate 110, in accordance with at least one example. In at least one example, passive devices 301, 302, 303, and 304 are bridge devices that couple terminals/ends of the inductor coils of the transformer to first and second semiconductor dies 101 and 102, respectively, over at least parts of the inductor coils. Each passive device can include, for example, a resistor, a capacitor, a bond wire, etc. In at least one example, substrate 110 includes a first metal layer 305 below a surface 315 (e.g., a top surface) of substrate 110. Substrate 110 further includes a second metal layer 307 below first metal layer 305, such that first metal layer 305 is vertically between surface 315 and second metal layer 307, and separated by a first dielectric layer 306 of substrate 110. In at least one example, the primary winding of the transformer is in first metal layer 305. In at least one example, second metal layer 307 is configured as a ground shield, which can be coupled to a ground plane (coupled to primary side ground terminal Vssp) external to the primary winding. The ground plane can provide a heat sink to dissipate heat from the primary winding of the transformer.

In at least one example, substrate 110 includes a third metal layer 308 below second metal layer 307. Substrate 110 further includes a fourth metal layer 310 below third metal layer 308 and separated by a second dielectric layer 309 of substrate 110. Fourth metal layer 310 is below a surface 325 (e.g., a bottom surface) of substrate 110, and fourth metal layer 310 is vertically between surface 325 and third metal layer 308. Isolation barrier 108, which can include the dielectric material of substrate 110, is vertically between second metal layer 307 and third metal layer 308. Isolation barrier 108 provides galvanic isolation between the primary and secondary windings of the transformer. In at least one example, the secondary winding of the transformer is in fourth metal layer 310. In at least one example, third metal layer 308 is configured as a ground shield, which can be coupled to another ground plane (coupled to secondary side ground terminal Vsss). The other ground plane can also provide a heat sink to dissipate heat from the secondary winding of the transformer.

In at least one example, the primary winding of transformer 106 can include a spiral coil or symmetric spiral coils in figure-of-8 or figure-of-B configurations and formed in first metal layer 305. In at least one example, the secondary winding of the transformer can be a spiral coil or symmetric coils in figure-of-8 or figure-of-B configurations and formed in fourth metal layer 310. In at least one example, passive devices 301 and 302 on the surface 315 of substrate 110 couple respective terminals of the symmetric coils of the primary winding to first semiconductor die 101. In at least one example, passive devices 303 and 304 on surface 325 of substrate 110 couple respective terminals of the symmetric coils of the secondary winding to second semiconductor die 102. In at least one example, first and second semiconductors dies 101 and 102, respectively, are flip-chip assemblies.

FIG. 3B is a schematic of an isometric view 320 of a portion of system 100 showing the top inductor (primary side inductor) above a ground plane, where the top inductor is coupled to the semiconductor die via passive components, in accordance with at least one example. FIG. 3C is a schematic of an isometric view 330 of system 100 showing the bottom inductor (secondary side inductor) above a ground plane, in accordance with at least one example. FIG. 3D is a schematic of an isometric view 340 of system 100 showing the ground planes adjacent to the top and bottom inductors, in accordance with at least one example.

In this example, the primary side winding comprises a figure-of-B inductor having a first coil 325a with first and second ends 326 and 327, respectively. As discussed herein the primary winding is formed in first metal layer 305. In this example, primary side power and ground is provided to first semiconductor die 101 in first metal layer 305. In at least one example, the primary side winding further includes a second coil 335b with third and fourth ends 328 and 329, respectively. In at least one example, first end 326 is coupled to third end 328 to couple first coil 325a to second coil 325b.

In at least one example, second end 327 is coupled to first passive component 301, which in turn is coupled to first semiconductor die 101 via a first metal interconnect 305a formed in first metal layer 305. First passive component 301 overlaps and bridges over first coil 325a. In at least one example, fourth end 329 is coupled to second passive component 302, which in turn is coupled to first semiconductor die 101 via a second metal interconnect 305b formed in first metal layer 305. Second passive component 302 overlaps and bridges over second coil 325b. In at least one example, first end 326 and third end 328 are coupled to a center tap 305c, which in turn is connected to a ground terminal (e.g., Vssp). Center tap 305c reduces parasitics of the primary winding, and conduct heat away and improve thermal performance of the primary winding. Center tap 305c also allows to better shunt the CMT current to ground without flowing through the IC thus providing increased immunity of the IC to ground transients/noise.

Referring to FIG. 3D, below first metal layer 305, is second metal layer 307, which includes traces 307a that overlap with first and second coils 325a and 325b, respectively, but with gaps and discontinuities 317 to avoid conducting a current induced by first and second coils 325a and 325b. In at least one example, second metal layer 307 under first and second coils 325a and 325b, respectively, is grounded to provide a noise shield. Second metal layer 307 includes a ground plane 307b external to first and second coils 325a and 325b. Ground plane 307b can operate as a heat sink, and traces 307a can conduct heat away from first and second coils 325a and 325b to ground plane 307b.

Also, below second metal layer 307 and isolation barrier 108 is third metal layer 308, which includes traces 308a that overlap with third and fourth coils 335a and 335b, respectively, but with gaps and discontinuities 318 to avoid conducting a current induced by third and fourth coils 335a and 335b. In at least one example, third metal layer 308 under third and fourth coils 335a and 335b, respectively, is grounded to provide a noise shield. Third metal layer 308 includes a ground plane 308b external to third and fourth coils 335a and 335b. Ground plane 308b can operate as a heat sink, and traces 308a can conduct heat away from third and fourth coils 335a and 335b to ground plane 308b.

In this example, the secondary side winding comprises a figure-of-B inductor having third coil 335a with first and second ends 336 and 337, respectively. As discussed herein the secondary winding is formed in fourth metal layer 310. In this example, secondary side power and ground is provided to second semiconductor die 102 in third metal layer 308. In at least one example, the secondary side winding further includes fourth coil 335b with third and fourth ends 338 and 339, respectively. In at least one example, first end 336 is coupled to third end 338 to couple third coil 335a to fourth coil 335b.

In at least one example, second end 337 is coupled to third passive component 303, which in turn is coupled to second semiconductor die 102 via a third metal interconnect 310a formed in fourth metal layer 310. In at least one example, fourth end 339 is coupled to fourth passive component 304, which in turn is coupled to second semiconductor die 102 via a fourth metal interconnect 310b formed in fourth metal layer 310. In at least one example, first end 336 and third end 338 are coupled to a center tap 310c, which in turn is connected to a ground terminal (e.g., Vssn). Center tap 310c reduces parasitics of the secondary winding and may be grounded to improve thermal performance of the secondary winding. Center tap 305c also allows to better shunt the common mode transient (CMT) current to ground without flowing through the IC thus providing increased immunity of the IC to ground transients/noise.

FIG. 4 is a schematic of an isometric view 400 of system 100 showing the top inductor (primary side inductor) above a ground plane, where the top inductor is coupled to the semiconductor die via bond wires, in accordance with at least one example. In at least one example, second end 327 of first coil 325a is coupled to first metal interconnect 305a via first bond wire 401. In at least one example, fourth end 329 of second coil 325b is coupled to second metal interconnect 305b via second bond wire 402. Similar bond wires couple second end 337 of third coil 335a to third metal interconnect 310a and fourth end 339 of fourth coil 335b to fourth metal interconnect 310b. Bond wires 401 and 402 can be examples of passive components 301 and 302.

FIGS. 5A-C are schematics of various configurations of the top/bottom inductors coupled to a passive device, in accordance with some examples. These configurations use a single passive device, which couples the one or more coils to first semiconductor die 101, in accordance with some examples. A single passive device may not have mismatch issues that may occur when two passive devices are used per transformer windings. While FIGS. 5A-C illustrate the configurations for the primary winding of transformer 106 and associated passive device(s), similar configurations can be made for the secondary winding of transformer 106.

Schematic 500 is a view of the primary winding with coil 325 configured as a spiral coil having first end 326 and second end 327. In at least one example, first end 326 is coupled to switching terminal sw2 and first semiconductor die 101. In at least one example, second end 327 is coupled to switching terminal sw1 and first semiconductor die 101 via bridge passive device 301, which overlaps and bridges over part of coil 325a. In at least one example, bridge passive device 301 is a capacitor, and a circuit representation of schematic 500 is illustrated in FIG. 2B. In at least one example, bridge passive device 301 is a bond wire or a resistor, and a circuit representation of schematic 500 is illustrated in FIG. 2A. Switching terminals sw1 and sw2 are coupled to first semiconductor die 101 through first and second metal interconnects 305a and 305b, respectively. Coil 325 is a compact configuration and being in spiral shape provides higher coupling factor (k) and higher quality factor (QF) for the same area.

Schematic 520 is a view of the primary winding configured as a figure-of-B having first coil 325a and second coil 325b. A circuit representation of schematic 520 is illustrated in FIG. 2C, where the primary side of transformer includes series coupled inductor L1a, capacitor C1, and inductor L1b. Inductor L1a can represent first coil 325a, inductor L1b can represent second coil 325b, and capacitor C1 can represent passive device 301. As discussed herein, the primary winding configured as a figure-of-B results in a symmetric pair of coils, first coil 325a and second coil 325b. Symmetric coils provide better far field EMI and improve communication reliability through the transformer. In at least one example, second end 327 of first coil 325a is coupled to a first terminal of passive device 301, and fourth end 329 of second coil 325b is coupled to a second terminal of passive device 301. As shown, passive device 301 overlaps and bridges over at least a part of first coil 325a and second coil 325b to provide an electrical connection (AC with a capacitor, DC with a resistor/bond wire) between first coil 325a and second coil 325b. In at least one example, first end 326 of first coil 325a is coupled to first semiconductor die 101 via first metal interconnect 305a, and second end 327 of second coil 325b is coupled to first semiconductor die 101 via second metal interconnect 305b.

Schematic 530 is a view of the primary winding configured as a figure-of-8 having first coil 325a and second coil 325b. A circuit representation of schematic 530 is illustrated in FIG. 2C, where the primary side of transformer includes series coupled inductor L1a, capacitor C1, and inductor L1b. As discussed herein, the primary winding configured as a figure-of-8 results in a symmetric pair of coils, first coil 325a and second coil 325b. Symmetric coils provide better far field EMI and improve communication reliability through the transformer. The figure-of-8 configuration also has lower radiated near field compared to figure-of-B configuration. In at least one example, second end 327 of first coil 325a is coupled to a first terminal of passive device 301, and fourth end 329 of second coil 325b is coupled to a second terminal of passive device 301. As shown, passive device 301 overlaps and bridges over at least a part of first coil 325a and second coil 325b to provide an electrical connection (AC with a capacitor, DC with a resistor/bond wire) between first coil 325a and second coil 325b. In at least one example, first end 326 of first coil 325a is coupled to first semiconductor die 101 via first metal interconnect 305a, and second end 327 of second coil 325b is coupled to first semiconductor die 101 via second metal interconnect 305b.

FIGS. 6A-C are schematics of various configurations of the top/bottom inductors coupled to two passive devices, in accordance with some examples. These configurations use two passive devices per winding, which couples the one or more coils to first semiconductor die 101, in accordance with some examples. While FIGS. 6A-C illustrate the configurations for the primary winding and associated passive device(s), similar configurations can be made for the secondary winding of the transformer.

A circuit representation of FIGS. 6A-C is illustrated in FIG. 2D, where passive device 301 can represent capacitor C1a, passive device 302 can represent capacitor C2a, and inductors L1a and L1b can represent coil 325, first coil 325a, and/or second coil 325b.

Schematic 600 is a view of the primary winding with coil 325 configured as a spiral coil having first end 326 and second end 327. In at least one example, first end 326 is coupled to switching terminal sw2 and first semiconductor die 101 via second passive device 302. In at least one example, second end 327 is coupled to switching terminal sw1 and first semiconductor die 101 via first passive device 301. In at least one example, passive devices 301 and 302 are a capacitor, resistor, or bond wire. As shown, passive device 301 overlaps and bridges over a first part of coil 325 to provide electrical connection (AC with a capacitor, DC with a resistor/bond wire) between switching terminal sw1 and second end 327. Also, passive device 302 overlaps and bridges over a second part of coil 325 to provide electrical connection (AC with a capacitor, DC with a resistor/bond wire) between switching terminal sw2 and first end 326. Switching terminals sw1 and sw2 are coupled to first semiconductor die 101 through first and second metal interconnects 305a and 305b, respectively. In at least one example, center tap 305c from coil 325 is connected to ground (GND). Center tap 305c improves thermals for coil 325 and reduces parasitic capacitance in coil 325, which improves the QF of coil 325. Coil 325 is a compact configuration and being in spiral shape provides higher k and QF for the same area.

Schematic 620 is a view of the primary winding configured as a figure-of-B having first coil 325a and second coil 325b. As described above, a circuit representation of schematic 530 is illustrated in FIG. 2D, where the primary side of transformer includes series coupled inductors L1a and inductor L1b with a center tap coupled to primary side ground terminal Vssp. First and second passive devices 301 and 302 are illustrated as capacitors C1a and C1b in FIG. 2D. As shown, passive device 301 overlaps and bridges over part of first coil 325a to provide electrical connection (AC with a capacitor, DC with a resistor/bond wire) between switching terminal sw1 and second end 327. Also, passive device 302 overlaps and bridges over a part of second coil 325b to provide electrical connection (AC with a capacitor, DC with a resistor/bond wire) between switching terminal sw2 and fourth end 329.

As discussed herein, the primary winding configured as a figure-of-B results in a symmetric pair of coils, first coil 325a and second coil 325b. Symmetric coils provide better far field EMI and improve communication reliability through the transformer. In at least one example, second end 327 of first coil 325a is coupled to a first terminal of first passive device 301, and fourth end 329 of second coil 325b is coupled to a first terminal of second passive device 302. In at least one example, first end 326 of first coil 325a is coupled third end 328, which in turn is coupled to center tap 305c. Center tap 305c may be grounded and is coupled to first semiconductor die 101. In at least one example, the second terminal of first passive device 301 is coupled to switching terminal sw1, which in turn is coupled to first semiconductor die 101 via first metal interconnect 305a. In at least one example, the second terminal of second passive device 302 is coupled to switching terminal sw2, which in turn is coupled to first semiconductor die 101 via second metal interconnect 305b. Center tap 305c improves thermals for the primary winding, which improves the QF of the primary winding. Center tap 305c also allows to better shunt the CMT current to ground without flowing through the IC thus providing increased immunity of the IC to ground transients/noise.

Schematic 630 is a view of the primary winding configured as a figure-of-8 having first coil 325a and second coil 325b. A circuit representation of schematic 530 is illustrated in FIG. 2C, where the primary side of transformer includes series coupled inductors L1a and inductor L1b with a center tap coupled to primary side ground terminal Vssp. First and second passive devices 301 and 302 are illustrated as capacitors C1a and C1b in FIG. 2D.

As discussed herein, the primary winding configured as a figure-of-8 results in a symmetric pair of coils, first coil 325a and second coil 325b. Symmetric coils provide better far field EMI and improve communication reliability through the transformer. The figure-of-8 configuration also has lower radiated near field compared to figure-of-B configuration. In at least one example, second end 327 of first coil 325a is coupled to the first terminal of first passive device 301. In at least one example, fourth end 329 of second coil 325b is coupled to the first terminal of second passive device 302.

In at least one example, first end 326 of first coil 325a is coupled third end 328 which in turn is coupled to center tap 305c. Center tap 305c may be grounded and is coupled to first semiconductor die 101. In at least one example, the second terminal of first passive device 301 is coupled to switching terminal sw1, which in turn is coupled to first semiconductor die 101 via first metal interconnect 305a. In at least one example, the second terminal of second passive device 302 is coupled to switching terminal sw2, which in turn is coupled to first semiconductor die 101 via second metal interconnect 305b. Center tap 305c improves thermals for the primary winding, which improves the QF of the primary winding. As shown, passive device 301 overlaps and bridges over part of first coil 325a to provide electrical connection (AC with a capacitor, DC with a resistor/bond wire) between switching terminal sw1 and second end 327. Also, passive device 302 overlaps and bridges over a part of second coil 325b to provide electrical connection (AC with a capacitor, DC with a resistor/bond wire) between switching terminal sw2 and fourth end 329.

FIGS. 7A-C are schematics of various stacks of system 100, in accordance with some examples. FIG. 7A illustrates a schematic view 700 of system 100, where substrate 110 is a 2-layer stack of layers with no heat sink layers and no vias. Here, bridge passive devices 301 and 302 are on the top surface of substrate 110 and bridge passive devices 303 and 304 are on top of the bottom surface of substrate 110. In at least one example, substrate 110 comprises first metal layer 305 to form the primary winding (e.g., spiral, figure-of-8, or figure-of-B coil configurations), such as first and second coils 325a and 325b. In at least one example, substrate 110 comprises fourth metal layer 310 to form the secondary winding (e.g., spiral, figure-of-8, or figure-of-B coil configurations), such as third and fourth coils 335a and 335b. In at least one example, first metal layer 304 is separated from fourth metal layer 310 by isolation barrier 108, which is a thick dielectric material (e.g., 300 μm or more in thickness along the z-direction) configured to provide galvanic isolation between the primary winding and the secondary winding. Other layers such as first and second thin dielectric layers 306 and 309, respectively, and second and third metal layers 307 and 308, respectively, are absent in the 2-layer stack.

FIG. 7B illustrates a schematic view 720 of system 100, where substrate 110 is a 4-layer stack of layers with internal heat sink layers and no vias. The heat sink layers also provide EMI shield. Here, bridge passive devices 301 and 302 are on the top surface of substrate 110 and bridge passive devices 303 and 304 are on top of the bottom surface of substrate 110. In at least one example, substrate 110 comprises first metal layer 305 to form the primary winding (e.g., spiral, figure-of-8, or figure-of-B coil configurations) such as first and second coils 325a and 325b.

In at least one example, substrate 110 comprises second metal layer 307 below first metal layer 305 and separated by first thin dielectric layer 306. As discussed herein, second metal layer 307 is a ground shield that reduces EMI and provides thermal or heat sink. In at least one example, substrate 110 comprises third metal layer 308 above fourth metal layer 310 and separated from fourth metal layer 310 by second thin dielectric layer 309. Fourth metal layer 310 is used to form the secondary winding (e.g., spiral, figure-of-8, or figure-of-B coil configurations), such as third and fourth coils 335a and 335b. In at least one example, second metal layer 307 is separated from third metal layer 308 by isolation barrier 108, which is a thick dielectric material (e.g., 8 mm or more in thickness along the z-direction) configured to provide galvanic isolation between the primary winding and the secondary winding.

FIG. 7C illustrates a schematic view 730 of system 100, where substrate 110 is a 6-layer stack of layers with internal heat sink layers and no vias. The heat sink layers also provide EMI shield. Here, bridge passive devices 301 and 302 are on the top surface of substrate 110 and bridge passive devices 303 and 304 are on top of the bottom surface of substrate 110. In at least one example, substrate 110 comprises first metal layer 305 to form the primary winding (e.g., spiral, figure-of-8, or figure-of-B coil configurations), such as first and second coils 325a and 325b.

In at least one example, substrate 110 comprises second metal layer 307 below first metal layer 305 and separated by first thin dielectric layer 306. As discussed herein, second metal layer 307 is a ground shield that reduces EMI and provides thermal or heat sink. In at least one example, substrate 110 comprises third metal layer 308 above fourth metal layer 310 and separated from fourth metal layer 310 by second thin dielectric layer 309. Fourth metal layer 310 is used to form the secondary winding (e.g., spiral, figure-of-8, or figure-of-B coil configurations), such as third and fourth coils 335a and 335b. In at least one example, second metal layer 307 is separated from third metal layer 308 by isolation barrier 108, which is a thick dielectric material (e.g., 8 mm or more in thickness along the z-direction) configured to provide galvanic isolation between the primary winding and the secondary winding. In at least one example, performance of galvanic isolation is further improved by using regions dedicated for metal layers 708a and 708b as dielectric above and below isolation barrier 108.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementations without changing the scope of disclosure.

Example 1 is an apparatus comprising: a substrate; a first coil below a surface of the substrate, the first coil having first and second ends; a second coil below the surface of the substrate and laterally adjacent to the first coil, the second coil having third and fourth ends; a semiconductor die on the surface of the substrate and coupled to the first and third ends via metal interconnects in the substrate; and a passive component on the surface of the substrate and coupled between the second end and the fourth end, the passive component overlapping at least parts of the first and second coils.

Example 2 is an apparatus according to any example herein, in particular example 1, wherein the first and second coils are part of a figure-of-8 coil.

Example 3 is an apparatus according to any example herein, in particular example 1, wherein the first and second coils are part of a figure-of-B coil.

Example 4 is an apparatus according to any example herein, in particular example 1, wherein the passive component includes at least one of: a resistor, a capacitor, or a bond wire.

Example 5 is an apparatus according to any example herein, in particular example 1, wherein the substrate includes a first metal layer and a second metal layer, wherein the first and second coils are in the first metal layer, wherein the second metal layer is configured as a ground shield, wherein the second metal layer is below the first metal layer.

Example 6 is an apparatus according to any example herein, in particular example 5, wherein the surface is a first surface, wherein the semiconductor die is a first semiconductor die, wherein the passive component is a first passive component, wherein the substrate has a second surface opposite to the first surface, wherein the metal interconnects are first metal interconnects, and wherein the apparatus comprises: a third coil below the second surface of the substrate, the third coil having first and second ends; a fourth coil below the second surface of the substrate and laterally adjacent to the third coil, the fourth coil having third and fourth ends; a second semiconductor die on the second surface of the substrate and coupled to the first and third ends via second metal interconnects in the substrate; and a second passive component on the second surface of the substrate and coupled between the second end and the fourth end, the second passive component overlapping at least parts of the third and fourth coils.

Example 7 is an apparatus according to any example herein, in particular example 6, wherein the third and fourth coils are part of a figure-of-8 coil.

Example 8 is an apparatus according to any example herein, in particular example 6, wherein the third and fourth coils are part of a figure-of-B coil.

Example 9 is an apparatus according to any example herein, in particular example 6, wherein the second passive component includes at least one of: a resistor, a capacitor, or a bond wire.

Example 10 is an apparatus according to any example herein, in particular example 9, wherein the ground shield is a first ground shield, wherein the substrate includes a third metal layer and a fourth metal layer, wherein the third and fourth coils are in the fourth metal layer, wherein the third metal layer is configured as a second ground shield, wherein the fourth metal layer is below the third metal layer.

Example 11 is an apparatus according to any example herein, in particular example 7, wherein the substrate includes an isolation barrier between the second metal layer and the third metal layer.

Example 12 is an apparatus according to any example herein, in particular example 6, wherein the first semiconductor includes a bridge inverter, and wherein the second semiconductor die includes bridge rectifier.

Example 13 is an apparatus according to any example herein, in particular example 1, wherein the substrate is a package substrate.

Example 14 is an apparatus according to any example herein, in particular example 1, wherein the substrate is a circuit board, and the semiconductor die is a packaged integrated circuit.

Example 15 is an apparatus comprising: a substrate; a coil below a surface of the substrate, the coil having first and second ends, and a center tap between the first and second ends, the center tap being coupled to a ground/reference terminal; a semiconductor die on the surface of the substrate; a first passive component on the surface of the substrate and coupled between the first end and the semiconductor die, the first passive component overlapping at least a part of the coil; and a second passive component on the surface of the substrate and coupled between the second end and the semiconductor die, the second passive component overlapping at least a part of the coil.

Example 16 is an apparatus according to any example herein, in particular example 15, wherein the coil is part of a figure-of-8 coil.

Example 17 is an apparatus according to any example herein, in particular example 15, wherein the coil is part of a figure-of-B coil.

Example 18 is an apparatus according to any example herein, in particular example 15, wherein the first and second passive components include at least one of: a resistor, a capacitor, or a bond wire.

Example 19 is an apparatus comprising: a substrate; a coil below a surface of the substrate, the coil having first and second ends; a semiconductor die on the surface of the substrate; and a capacitor on the surface of the substrate and coupled between the first end and the semiconductor die, the semiconductor die coupled to the second end via a metal interconnect in the substrate, the capacitor overlapping at least a part of the coil.

Example 20 is an apparatus according to any example herein, in particular example 19, wherein the coil is part of a figure-of-8 coil.

Example 21 is an apparatus according to any example herein, in particular example 19, wherein the coil is part of a figure-of-B coil.

Example 22 is an apparatus according to any example herein, in particular example 19, wherein the substrate is a package substrate.

Example 23 is an apparatus according to any example herein, in particular example 19, wherein the substrate is a circuit board, and the semiconductor die is a packaged integrated circuit.

Example 24 is an apparatus according to any example herein, in particular example 19, wherein the substrate includes a first metal layer and a second metal layer, wherein the coil is in the first metal layer, wherein the second metal layer is configured as a ground shield, wherein the second metal layer is below the first metal layer.

Example 25 is an apparatus according to any example herein, in particular example 19, wherein the surface is a first surface, wherein the semiconductor die is a first semiconductor die, wherein the coil is a first coil, wherein the substrate has a second surface opposite to the first surface, wherein the metal interconnect is a first metal interconnect, and wherein the apparatus comprises: a second coil below the second surface of the substrate, the second coil having third and fourth ends; a second semiconductor die on the second surface of the substrate; and a second capacitor on the second surface of the substrate and coupled between the third and fourth ends, the second semiconductor die coupled to the fourth end via a second metal interconnect in the substrate, the second capacitor overlapping at least a part of the second coil.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including,” and “having,” and variants thereof are intended to be inclusive in a manner similar to the term “comprising” unless otherwise noted. In addition, the terms “couple,” “coupled,” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a substrate;
a first coil below a surface of the substrate, the first coil having first and second ends;
a second coil below the surface of the substrate and laterally adjacent to the first coil, the second coil having third and fourth ends;
a semiconductor die on the surface of the substrate and coupled to the first and third ends via metal interconnects in the substrate; and
a passive component on the surface of the substrate and coupled between the second end and the fourth end, the passive component overlapping at least parts of the first and second coils.

2. The apparatus of claim 1, wherein the first and second coils are part of a figure-of-8 coil.

3. The apparatus of claim 1, wherein the first and second coils are part of a figure-of-B coil.

4. The apparatus of claim 1, wherein the passive component includes at least one of: a resistor, a capacitor, or a bond wire.

5. The apparatus of claim 1, wherein the substrate includes a first metal layer and a second metal layer, wherein the first and second coils are in the first metal layer, wherein the second metal layer is configured as a ground shield, wherein the second metal layer is below the first metal layer.

6. The apparatus of claim 5, wherein the surface is a first surface, wherein the semiconductor die is a first semiconductor die, wherein the passive component is a first passive component, wherein the substrate has a second surface opposite to the first surface, wherein the metal interconnects are first metal interconnects, and wherein the apparatus comprises:
a third coil below the second surface of the substrate, the third coil having first and second ends;
a fourth coil below the second surface of the substrate and laterally adjacent to the third coil, the fourth coil having third and fourth ends;
a second semiconductor die on the second surface of the substrate and coupled to the first and third ends via second metal interconnects in the substrate; and
a second passive component on the second surface of the substrate and coupled between the second end and the fourth end, the second passive component overlapping at least parts of the third and fourth coils.

7. The apparatus of claim 6, wherein the third and fourth coils are part of a figure-of-8 coil.

8. The apparatus of claim 6, wherein the third and fourth coils are part of a figure-of-B coil.

9. The apparatus of claim 6, wherein the second passive component includes at least one of: a resistor, a capacitor, or a bond wire.

10. The apparatus of claim 6, wherein the ground shield is a first ground shield, wherein the substrate includes a third metal layer and a fourth metal layer, wherein the third and fourth coils are in the fourth metal layer, wherein the third metal layer is configured as a second ground shield, wherein the fourth metal layer is below the third metal layer.

11. The apparatus of claim 10, wherein the substrate includes an isolation barrier between the second metal layer and the third metal layer.

12. The apparatus of claim 6, wherein the first semiconductor includes a bridge inverter, and wherein the second semiconductor die includes bridge rectifier.

13. The apparatus of claim 1, wherein the substrate is a package substrate.

14. The apparatus of claim 1, wherein the substrate is a circuit board, and the semiconductor die is a packaged integrated circuit.

15. An apparatus comprising:
a substrate;
a coil below a surface of the substrate, the coil having first and second ends, and a center tap between the first and second ends, the center tap being coupled to a ground terminal;
a semiconductor die on the surface of the substrate;
a first passive component on the surface of the substrate and coupled between the first end and the semiconductor die, the first passive component overlapping at least a part of the coil; and
a second passive component on the surface of the substrate and coupled between the second end and the semiconductor die, the second passive component overlapping at least a part of the coil.

16. The apparatus of claim 15, wherein the coil is part of a figure-of-8 coil.

17. The apparatus of claim 15, wherein the coil is part of a figure-of-B coil.

18. The apparatus of claim 15, wherein the first and second passive components include at least one of: a resistor, a capacitor, or a bond wire.

19. An apparatus comprising:
a substrate;
a coil below a surface of the substrate, the coil having first and second ends;
a semiconductor die on the surface of the substrate; and
a capacitor on the surface of the substrate and coupled between the first end and the semiconductor die, the semiconductor die coupled to the second end via a metal interconnect in the substrate, the capacitor overlapping at least a part of the coil.

20. The apparatus of claim 19, wherein the coil is part of a figure-of-8 coil.

21. The apparatus of claim 19, wherein the coil is part of a figure-of-B coil.

22. The apparatus of claim 19, wherein the substrate is a package substrate.

23. The apparatus of claim 19, wherein the substrate is a circuit board, and the semiconductor die is a packaged integrated circuit.

24. The apparatus of claim 19, wherein the substrate includes a first metal layer and a second metal layer, wherein the coil is in the first metal layer, wherein the second metal layer is configured as a ground shield, wherein the second metal layer is below the first metal layer.

25. The apparatus of claim 19, wherein the surface is a first surface, wherein the semiconductor die is a first semiconductor die, wherein the coil is a first coil, wherein the substrate has a second surface opposite to the first surface, wherein the metal interconnect is a first metal interconnect, and wherein the apparatus comprises:
a second coil below the second surface of the substrate, the second coil having third and fourth ends;
a second semiconductor die on the second surface of the substrate; and
a second capacitor on the second surface of the substrate and coupled between the third and fourth ends, the second semiconductor die coupled to the fourth end via a second metal interconnect in the substrate, the second capacitor overlapping at least a part of the second coil.
